(19) United States
(12) Patent Application Publication
(10) Pub. No.: US 2006/0166481 A1
(43) Pub. Date: Jul. 27, 2006

(54) Method of forming metal layer pattern and method of manufacturing image sensor using the same

(75) Inventors: Gyoo-Dong Kim, Hwaseong-si (KR); Young-Bum Hwangbo, Suwon-si (KR); Jong-Min Oh, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/328,765

(22) Filed: Jan. 10, 2006

(30) Foreign Application Priority Data
Jan. 25, 2005 (KR) 10-2005-0006850

(51) Int. Cl. H01L 21/4763

(52) U.S. Cl. 438/622

(57) ABSTRACT

A method of forming a metal layer pattern comprises forming an interlayer insulating layer on a semiconductor substrate, forming a metal layer on the interlayer insulating layer, forming a mask pattern to expose a predetermined area of the metal layer, and forming a metal layer pattern by dry etching the exposed predetermined area of the metal layer with a substrate bias power of about 5 W to about 40 W.

### CROSS-REFERENCE TO RELATED APPLICATION

This application claims priority to Korean Patent Application No. 10-2005-0006850, filed on Jan. 25, 2005, the disclosure of which is incorporated herein in its entirety by reference.

### BACKGROUND OF THE INVENTION

1. Technical Field

The present disclosure relates to a method of manufacturing a semiconductor device and more particularly to a method of forming a metal layer pattern and a method of manufacturing an image sensor using the method of forming the metal layer pattern.

2. Discussion of the Related Art

Image sensors convert optical images into electrical signals. The image sensors are used to store, transmit, and display the image signals. The image sensors can be classified into solid-state image pickup devices, such as a charge coupled device (CCD), and complementary metal oxide semiconductor (CMOS) image sensors (CIS), which are based on silicon semiconductors. The solid-state image pickup devices, such as CCD, generate less noise, and have better image quality, and smaller sizes in comparison with the CMOS image sensors (CIS). The CMOS image sensors (CIS) have lower production cost and less power consumption in comparison with the solid-state image pickup devices. The CMOS image sensors (CIS) are more easily integrated with chips of peripheral circuits than the solid-state image pick-up devices. Electronic devices having the image sensors include, for example, digital cameras and camera phones. Photo sensitivity of the image sensors affects the image quality of the electronic devices.

Conventional image sensors generally include a photo diode and a light-shielding layer pattern. An interlayer insulating layer comprising silicon oxide can be interposed between the photo diode and the light-shielding layer pattern. The interlayer insulating layer can affect the photo sensitivity of the image sensors. For example, when the thickness of the interlayer insulating layer is substantially large, a smear phenomenon can occur.

A method of manufacturing a solid-state image pickup device including a process of etching a metal layer comprising tungsten is known. In the method, an etching process using a substrate bias power of 45 W is performed on the tungsten layer, which is used as the light-shielding layer, to improve the uneven etching of the tungsten layer. However, the process of etching the tungsten layer with the substrate bias power can substantially damage a silicon oxide layer under the tungsten layer.

A method of manufacturing a solid-state image pickup device to prevent the etching damage to the silicon oxide layer under the tungsten layer is known. To prevent the damage to a silicon oxide layer formed under the tungsten layer caused by etching the tungsten layer, an etching prevention layer is formed on a semiconductor substrate having the silicon oxide layer and then the tungsten layer is formed thereon. The etching prevention layer may comprise titanium compound. However, the manufacturing method may be complicated with the formation of the etching prevention layer. Furthermore, since the substrate bias power of 50 W is used in the etching process, it may be difficult to prevent the damage on the silicon oxide layer.

In conventional methods, the tungsten layer can be used as the light-shielding layer of an image sensor. However, the substrate bias power of 40 W or more is used to etch the tungsten layer. For example, in a known method of etching the tungsten layer, a substrate bias power of 40 W to 800 W is used to etch the tungsten layer. The process of etching the tungsten layer using the substrate bias power of 40 W or more may substantially damage an insulating layer under the tungsten layer. Accordingly, the photo sensitivity of an image sensor can be deteriorated due to the damage to the insulating layer generated in the process of etching the tungsten layer for forming a light-shielding pattern of the image sensor.

### SUMMARY OF THE INVENTION

Embodiments of the present invention provide a method of forming a metal layer pattern and a method of manufacturing an image sensor, in which a metal layer pattern is formed by performing a dry etching process to a metal layer so as not to practically damage an interlayer insulating layer under the metal layer.

According to an embodiment of the present invention, a method of forming a metal layer pattern comprises forming an interlayer insulating layer on a semiconductor substrate, forming a metal layer on the interlayer insulating layer, forming a mask pattern to expose a predetermined area of the metal layer, and forming a metal layer pattern by dry etching the exposed predetermined area of the metal layer with a substrate bias power of about 5 W to about 40 W.

The metal layer may comprise a tungsten layer.

The interlayer insulating layer may comprise a silicon oxide layer.

The substrate bias power may be in the range of about 5W to about 20 W.

The dry etching process may include performing a main etching process for etching a substantial portion of the exposed predetermined area of the metal layer by using a first plasma source gas, and performing an over-etching process for etching the remaining portion of the exposed predetermined area of the metal layer using a second plasma source gas. The second plasma source gas may comprise the same gas as the first plasma source gas. The first and second plasma source gases may include a fluorine species. The first and second plasma source gases may comprise sulfur hexafluoride (SF₆).

A plasma source power of about 200 W to about 2000 W may be used in the dry etching process.

According to another embodiment of the present invention, a method of manufacturing an image sensor comprises preparing a semiconductor substrate having a photo diode, forming an interlayer insulating layer on the semiconductor substrate, forming a metal layer on the interlayer insulating layer, forming a mask pattern on the metal layer to expose a predetermined area of the metal layer, and forming a metal layer pattern exposing a portion of the interlayer insulating layer on the photo diode by dry etching the exposed predetermined area of the metal layer with a substrate bias power of about 5 W to about 40 W.

The metal layer may comprise a tungsten layer.

The interlayer insulating layer may comprise a silicon oxide layer. The mask pattern may be formed with a photo resist pattern.

The substrate bias power may be in the range of about 5 W to about 20 W.

The dry etching process may include performing a main etching process for etching a substantial portion of the exposed predetermined area of the metal layer by using a first plasma source gas, and performing an over-etching process for etching a remaining portion of the exposed predetermined area of the metal layer using a second plasma source gas. The second plasma source gas may comprise the same gas as the first plasma source gas. The first and second plasma source gases may include a fluorine species. The first and second plasma source gases may be composed of sulfur hexafluoride (SF₆).

A plasma source power of about 200W to about 2000 W may be used in the dry etching process.

### BRIEF DESCRIPTION OF THE DRAWINGS

Exemplary embodiments of the present invention can be understood in more detail from the following description taken in conjunction with the accompanying drawings in which:

FIG. 1 to FIG. 3 are cross-sectional views illustrating a method of manufacturing an image sensor according to an embodiment of the present invention; and

FIG. 4 is a graph illustrating a thickness of an oxide layer that is lost versus substrate bias power in a dry etching process.

### DETAILED DESCRIPTION OF THE EXEMPLARY EMBODIMENTS

Exemplary embodiments of the present invention will be described below in more detail with reference to the accompanying drawings. However, the present invention should not be construed as being limited to the exemplary embodiments set forth herein, but may be embodied in many different forms.

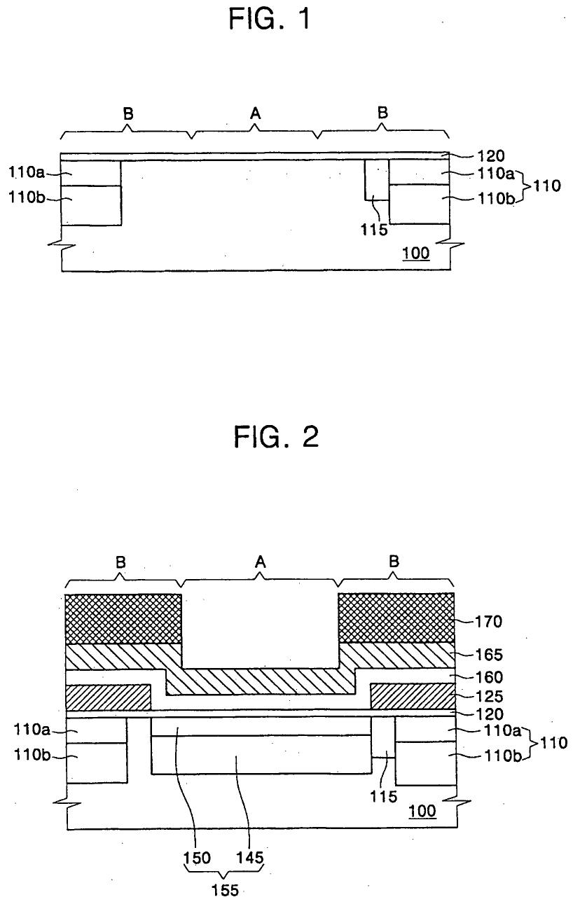

FIGS. 1 to 3 are cross-sectional views illustrating a method of manufacturing an image sensor according to an embodiment of the present invention.

Referring to FIGS. 1, 2 and 3, a semiconductor substrate 100 includes a light-receiving region A and a light-shielding region B. The semiconductor substrate 100 may be a P-type well. A dielectric layer 120 is formed on the semiconductor substrate 100. The dielectric layer 120 may be formed with an ONO (silicon oxide/silicon nitride/silicon oxide) layer or a silicon oxide layer. A channel stop region 115 and a vertical transport region 110 can be formed in the semiconductor substrate 100 by using a conventional method, respectively. The channel stop region 115 may be a region into which Group III impurity ions are implanted. The vertical transport region 110 may include an n-type transport channel region 110a and a p-type transport channel region 110b.

A conductive layer is formed on the dielectric layer 120. A transport electrode 125 is formed by patterning the conductive layer. The transport electrode 125 may comprise a poly silicon layer. The transport electrode 125 may be formed as an electrode having one layer or multi layers. For example, when the transport electrode 125 has a two-layer structure, a first transport electrode layer is formed by patterning a first conductive layer. Subsequently, an interlayer dielectric layer is formed on the semiconductor substrate having the first transport electrode layer and then a second conductive layer is formed thereon. Then, a second transport electrode layer is formed by patterning the second conductive layer. In an embodiment of the present invention, the first conductive layer and the second conductive layer may comprise a poly silicon layer.

A photo diode 155 is formed in the light-receiving region A of the semiconductor substrate 100. The photo diode 155 may include an n-type impurity region 145 and a hole accumulation region 150 formed using, for example, ion implantation processes. For example, the n-type impurity region 145 is formed by implanting n-type impurity ions using the transport electrode 125 in the light-receiving region A of the semiconductor substrate 100 as an ion implantation mask. By implanting p-type impurity ions into the upper region of the n-type impurity region 145, the hole accumulation region 150 is formed.

In an embodiment of the present invention, the ion implantation processes for forming the photo diode 155 can be performed when the dielectric layer 120 is not altered. In another embodiment of the present invention, before performing the ion implantation processes, the dielectric layer 120 in the light-receiving region A can be removed by using the transport electrode 125 as a mask and then a single-layer silicon oxide layer can be formed. In another embodiment of the present invention, when the dielectric layer 120 is formed with an ONO layer, the ion implantation processes can be performed when the silicon oxide layer at the lowermost portion of the ONO layer remains.

After performing the ion implantation processes, impurity ions resulting from the ion implantation processes may be trapped in the dielectric layer 120 of the light-receiving region A. The impurity ions trapped in the dielectric layer 120 may be diffused into the photo diode 155 by a subsequent heat treatment. The impurity ions trapped in the dielectric layer 120 can lower the sensitivity of the image sensor. Accordingly, after performing the ion implantation processes, the dielectric layer 120 in the light-receiving region A may be removed and then another dielectric layer may be formed in the light-receiving region A of the semiconductor substrate. The new dielectric layer formed in the light-receiving region A of the semiconductor substrate 100 may be formed with a silicon oxide layer.

Referring to FIG. 2, an interlayer insulating layer 160 is formed on the entire surface of the resultant semiconductor substrate. The interlayer insulating layer 160 may comprise a silicon oxide layer. For example, the interlayer insulating layer 160 may comprise a high-temperature oxide layer. As the interlayer insulating layer 160 becomes thinner, the characteristic of the image sensor can be improved. That is, a thin interlayer insulating layer 160 can prevent a smear phenomenon occurring in the image sensor such as a solid-state image pickup device.

A metal layer 165 is formed on the entire surface of the interlayer insulating layer 160. The metal layer 165 can comprise, for example, tungsten. Subsequently, a mask pattern 170 exposing the light-receiving region A is formed on the metal layer 165. The mask pattern 170 may be formed with a photoresist pattern.

Referring to FIG. 3, a metal layer pattern 165a is formed by performing a dry etching process using the mask pattern 170 as an etching mask to the metal layer 165. Substrate bias power of about 5 W to about 40 W is used in the dry etching process. In an embodiment of the present invention, the dry etching process includes a main etching process of etching a substantial portion, for example, a majority of the exposed metal layer 165 by using a first plasma source gas and an over-etching process of etching the remaining portion of the exposed metal layer by using a second plasma source gas. The main etching process can be performed up to an end of point (EOP). The over-etching process can be performed to etch the remaining metal layer which has not been etched in the main etching process. The main etching process and the over-etching process can be performed under the same conditions except for the process time. The second plasma source gas used in the over-etching process may be the same as the first plasma source gas used in the main etching process.

A plasma source gas including a chemically functional etchant species of a halogen group can be used in the dry etching process. For example, a fluorine species can be included in the plasma source gas. The fluorine species can remove oxides and other remaining materials generated on the surface of the tungsten layer when tungsten is exposed to air in the etching process. Therefore, according to an embodiment of the present invention, the etching process is performed using the plasma source gas including the fluorine species. The plasma source gas including, for example, the fluorine species and an inert gas such as, for example, argon (Ar) used as a non-reactive diluent gas can be used together in the dry etching process.

According to embodiments of the present invention, the dry etching process uses the plasma source gas including, for example, the fluorine species under the condition of a process chamber pressure of about 2 mTorr to about 24 mTorr and a flow rate of about 10 sccm to about 100 sccm and the non-reactive diluent gas under the condition of a flow rate of about 10 sccm to about 100 sccm. For example, sulphur hexafluoride (SF₆) can be used as the plasma source gas. Argon can be used as the non-reactive diluent gas. The dry etching process can use a plasma source power of about 200 W to about 2000 W. To further reduce the etching damage on the interlayer insulating layer 160 formed under the metal layer 165, the substrate bias power of about 5 W to about 20 W can be used. The plasma source power is defined as the power for maintaining the plasma state in the dry etching process. The substrate bias power is defined as the power to be applied to the substrate to guide the plasma species toward the semiconductor substrate 100.

An experiment has been performed to show to which extent the interlayer insulating layer 160 loses thickness from the process of forming the metal layer pattern 165a according to an embodiment of the present invention. The experiment has been performed using a photolithography process and a photo mask used in manufacturing the image sensor.

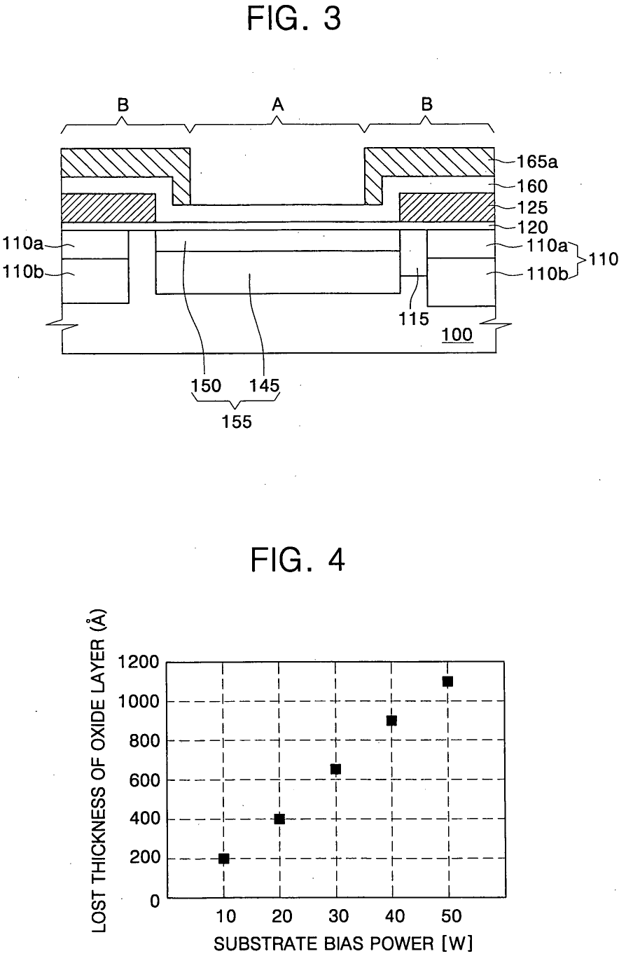

FIG. 4 is a graph illustrating the lost thickness of the oxide layer with respect to the substrate bias power in the dry etching process. In FIG. 4, the X axis denotes the substrate bias power in the dry etching process and the Y axis denotes the lost thickness of the oxide layer.

Referring to FIGS. 1-4, a conductive layer pattern having the same size and shape as the transport electrode 125 is formed on the semiconductor substrate 100. Subsequently, the interlayer insulating layer 160 having a thickness of about 2100 Å is formed on the semiconductor substrate 100. For example, the interlayer insulating layer 160 is a silicon oxide layer comprising high-temperature oxide. Subsequently, the metal layer 165 such as a tungsten layer is formed on the interlayer insulating layer. The tungsten layer is formed using, for example, a sputtering method. Next, a mask pattern such as a photo resist layer pattern having the same pattern as the mask layer pattern for exposing the light-receiving region A in embodiments of the present invention is formed on the tungsten layer. That is, the tungsten layer in the light-receiving region A is exposed by the photo resist layer pattern.

The dry etching process includes the main etching process and the over-etching process. The substantial portion, for example, a majority of the exposed tungsten layer is etched in the main etching process and the remaining tungsten layer is etched in the over-etching process. The main etching process and the over-etching process are performed under substantially the same conditions. That is, in the main etching process and the over-etching process according to an embodiment of the present invention, SF₆ with the flow rate of about 45 sccm is used as the plasma source gas and Ar with the flow rate of about 60 sccm is used as the non-reactive diluent gas. The plasma source power of, for example, about 600 W is used. Most of the tungsten layer is etched in the main etching process. The over-etching process is performed for about 30 seconds.

The dry etching processes using 10 W, 20 W, 30 W, 40 W, and 50 W as the substrate bias power were performed. As a result, as shown in FIG. 4, the silicon oxide layer is etched and lost by about 200 Å, about 400 Å, about 650 Å, about 900 Å, and about 1100 Å, respectively. Thus, because less of the oxide layer is lost when less substrate bias power is used, the thickness of the interlayer insulating layer 160 of the image sensor can be thinner when manufacturing the image sensor using the method of forming the metal layer pattern with the substrate bias power of about 40 W or less. The lost thickness of the interlayer insulating layer 160 also depends on the diameter of a semiconductor wafer, the over-etching process time, and the kinds of etching equipment.

Accordingly, although the thickness of the interlayer insulating layer 160 is not specified, the thickness of the interlayer insulating layer can be made smaller when using the method of forming the metal layer pattern according to an embodiment of the present invention. According to the method of manufacturing an image sensor using the method of forming the metal layer pattern, since the thickness of the interlayer insulating layer 160 of the image sensor can be made smaller, the smear phenomenon occurring in the image sensor can be prevented. Therefore, the photo sensitivity of the image sensor can be improved.

According to embodiments and experiments of the present invention described above, the etching damage on the interlayer insulating layer 160 exposed in the dry etching process due to the formation of the metal layer pattern 165a can be minimized. As a result, it is possible to prevent deterioration of characteristics due to the etching damage on the interlayer insulating layer 160. In addition, since less of the oxide layer is lost, the thickness of the interlayer insulating layer 160 can be further smaller, and the smear phenomenon of the image sensor can be prevented.

Accordingly, etching damage to the interlayer insulating layer 160 can be minimized in the method of forming the metal layer pattern 165a according to embodiments of the present invention and the photo sensitivity of the image sensor manufactured using the method can be improved.

According to embodiments of the present invention described above, it is possible to minimize the etching damage on the interlayer insulating layer 160 under the light-shielding layer due to the process of etching a metal layer as a light-shielding layer.

Although exemplary embodiments have been described with reference to the accompanying drawings, it is to be understood that the present invention is not limited to these precise embodiments but various changes and modifications can be made by one skilled in the art without departing from the spirit and scope of the present invention. All such changes and modifications are intended to be included within the scope of the invention as defined by the appended claims.

What is claimed is:

1. A method of forming a metal layer pattern, the method comprising:
forming an interlayer insulating layer on a semiconductor substrate;
forming a metal layer on the interlayer insulating layer;
forming a mask pattern to expose a predetermined area of the metal layer; and
forming a metal layer pattern by dry etching the exposed predetermined area of the metal layer with a substrate bias power of about 5 W to about 40 W.

2. The method according to claim 1, wherein the metal layer comprises a tungsten layer.

3. The method according to claim 1, wherein the interlayer insulating layer comprises a silicon oxide layer.

4. The method according to claim 1, wherein the substrate bias power is in the range of about 5 W to about 20 W.

5. The method according to claim 1, wherein the dry etching process includes:
performing a main etching process for etching a substantial portion of the exposed predetermined area of the metal layer by using a first plasma source gas; and
performing an over-etching process for etching a remaining portion of the exposed predetermined area of the metal layer using a second plasma source gas.

6. The method according to claim 5, wherein the second plasma source gas comprises the same gas as the first plasma source gas.

7. The method according to claim 6, wherein the first and second plasma source gases include a fluorine species.

8. The method according to claim 7, wherein the first and second plasma source gases comprise sulfur hexafluoride (SF₆).

9. The method according to claim 1, wherein a plasma source power of about 200 W to about 2000 W is used in the dry etching process.

10. A method of manufacturing an image sensor, the method comprising:
preparing a semiconductor substrate having a photo diode;
forming an interlayer insulating layer on the semiconductor substrate;
forming a metal layer on the interlayer insulating layer;
forming a mask pattern on the metal layer to expose a predetermined area of the metal layer; and
forming a metal layer pattern exposing a portion of the interlayer insulating layer on the photo diode by dry etching the exposed predetermined area of the metal layer with a substrate bias power of about 5 W to about 40 W.

11. The method according to claim 10, wherein the metal layer comprises a tungsten layer.

12. The method according to claim 10, wherein the interlayer insulating layer comprises a silicon oxide layer.

13. The method according to claim 10, wherein the mask pattern is formed with a photoresist pattern.

14. The method according to claim 10, wherein the substrate bias power is in the range of about 5 W to about 20 W.

15. The method according to claim 10, wherein the dry etching process includes:
performing a main etching process for etching a substantial portion of the exposed predetermined area of the metal layer by using a first plasma source gas; and
performing an over-etching process for etching a remaining portion of the exposed predetermined area of the metal layer using a second plasma source gas.

16. The method according to claim 15, wherein the second plasma source gas comprises the same gas as the first plasma source gas.

17. The method according to claim 16, wherein the first and second plasma source gases include a fluorine species.

18. The method according to claim 17, wherein the first and second plasma source gases comprise sulfur hexafluoride (SF₆).

19. The method according to claim 10, wherein a plasma source power of about 200 W to about 2000 W is used in the dry etching process.
